(19) United States
(12) Patent Application Publication
(10) Pub. No.: US 2005/0211896 A1
(43) Pub. Date: Sep. 29, 2005

(54) PT COATING INITIATED BY INDIRECT ELECTRON BEAM FOR RESIST CONTACT HOLE METROLOGY

(75) Inventors: Wei Lu, Poughkeepsie, NY (US); Chester Wasik, Poughkeepsie, NY (US)

Correspondence Address: FREDERICK W. GIBB, III;MCGINN & GIBB, PLLC, 2568-A RIVA ROAD, SUITE 304, ANNAPOLIS, MD, 21401, US

(73) Assignee: INTERNATIONAL BUSINESS MACHINES CORPORATION, Armonk, NY (US)

(21) Appl. No.: 10/708,748

(22) Filed: Mar. 23, 2004

(51) Int. Cl. G21K 7/00; H01L 21/00

(52) U.S. Cl. 250/307; 250/311

(57) ABSTRACT

The invention surrounds a partially completed integrated circuit structure, having topographical features such as rvias with a precursor organic metal gas and then directs an angled electron beam at the partially completed integrated circuit structure to create secondary electron beams as the angled electron beam strikes the sidewalls of vias. The secondary electron beams break down the precursor metal gas to form a metal coating, without damaging the top layer (or underlying layers). This process directs the electron beam at an angle sufficient to cause the electron beam to strike only the sidewalls of the vias and prevent the electron beam from reaching the bottom of the vias, so as to not damage the vias during the metal formation process. After the protective metal layer is formed, the invention directs an ion beam at the partially completed integrated circuit structure to form a groove within the top layer and allows inspection of the cross sections of the vias exposed by the groove.

### BACKGROUND OF INVENTION

The present invention generally relates to a method of inspecting topographical features in partially completed structures and more particularly to a method that uses an angled electron beam when depositing a protective thin metal layer prior to an ion beam cutting process, where the angled ion beam avoids damaging the features being inspected.

Dual Beam (DB) tools use both a focused ion beam (FIB) column and scanning electron microscopy (SEM). The FIB is used to mill through a feature on the top of a processing wafer or sample without breaking the wafer or sample, and forming a vertical cross-section showing the interested feature on it. The stage is designed with a variable tilt angle to show the cross-section and reveal the feature underneath the top surface.

For viewing resist feature cross-sections with DB technology, the following steps are usually involved. First, metal (such as Pt, W) deposition occurs to fully cover the interested area. A precursor gas is provided (typically an organic metal compound), which will deposit metal when irradiated by the ion beam. The purpose of the coating is to allow the top surface of the resist to be clearly identified by increasing the top surface contrast for the SEM image and protect the underlying material from damage during FIB milling.

Secondly, by using a low current ion beam (typically Ga) a section, groove, or channel is cut (referred to as milling) from the resist feature. The resist layer is typically formed over an anti-reflective coating (ARC) layer or other substrate. The milling procedure removes roughly a rectangular section (in plane view) of the resist to a depth just below the feature of interest, which may mill away some of the underlying layer. The edge of the milled region is targeted to expose a cross-section of the features to be imaged. Sometimes, chemistry can be used to enhance the ion beam etching rate on resist, which is called Gas Assisted Etching (GAE). Third, the SEM is used to take a tilt angled image to reveal the 3D profile of the feature of interest.

The topographical feature profiles are sensitive to beam sources (FIB, SEM, etc), which can undesirably cause top-corner widening, edge rounding, and deform the original shape and dimension of the topographical feature. Both the metal deposition and the ion beam milling can damage the contact features that are to be observed, causing sharp contour change, such as resist lipping, contact bottom footing, and recession. This frustrates the purpose of the inspection process by damaging the features that are desired to be observed. GAE can enhance the resist etching rate and decrease the total etching time. However, the gas which is activated by the incoming beam reacts with the resist and can reach a wider range than the incoming beam, thereby undesirably damaging the interested feature profile being observed. As a result, all detailed features that are to be observed will be rounded out, further frustrating the inspection process.

### SUMMARY OF INVENTION

The invention provides a method of inspecting topographical features, such as vias, of the top layer of a partially completed structure (e.g., integrated circuit). More specifically, the invention surrounds the partially completed integrated circuit structure with a precursor organic metal gas and then directs an angled electron beam at the partially completed integrated circuit structure to create secondary electron beams as the angled electron beam strikes the sidewalls of the vias. The secondary electron beams break down the precursor metal gas to form a metal coating, without damaging the top layer (or under-lying layers of the structure). This process directs the electron beam at an angle sufficient to cause the electron beam to strike only the sidewalls of the vias and prevent the electron beam from reaching the bottom of the vias, so as to not damage the vias during the metal formation process. After the protective metal layer is formed, the invention directs an ion beam at the partially completed integrated circuit structure to form a groove within the top layer and inspects the cross sections of the vias exposed by the groove.

The process of directing the angled electron beam comprises tilting a stage that supports the partially completed integrated circuit structure. The secondary electron beam has much less energy than the angled electron beam and the angled electron beam has an energy level of approximately between 100 and 10,000 electron volts.

When the primary electron beam hits a surface, the emitted electrons that have an energy level less than 50 eV are called secondary electrons, and those with an energy level of 50 eV or higher are called backscattered electrons. The lower power secondary electrons are usually much more abundant relative to backscattered electrons. The same electron beam can be shared for both imaging and deposition, where the direct beam is used for imaging, and the indirect beam is used for metal deposition to form a true protection layer without deforming or damaging the underlying resist feature because of the nature of the low energy of the indirect beam. The indirect electrons initiate the metal deposition (using the precursor gas). Thus, the present invention provides the indirect electron beam as an energy source to initiate metal coating with the existence of precursor gas, and also offers a coating technique to cover a wide range of applications on the variety of materials, topography, shapes, etc.

These, and other, aspects and objects of the present invention will be better appreciated and understood when considered in conjunction with the following description and the accompanying drawings. It should be understood, however, that the following description, while indicating preferred embodiments of the present invention and numerous specific details thereof, is given by way of illustration and not of limitation. Many changes and modifications may be made within the scope of the present invention without departing from the spirit thereof, and the invention includes all such modifications.

### BRIEF DESCRIPTION OF DRAWINGS

The invention will be better understood from the following detailed description with reference to the drawings, in which:

FIG. 1 is a schematic diagram of an exemplary focused ion beam system;

FIG. 2 is a schematic diagram of a structure undergoing processing in a focused ion beam system;

FIG. 3 is a schematic diagram of a structure undergoing processing in a focused ion beam system;

FIG. 4 is a schematic diagram of a structure undergoing processing in a focused ion beam system;

FIG. 5 is a schematic diagram of a structure undergoing processing in a focused ion beam system; and

FIG. 6 is an expanded schematic diagram of a feature undergoing processing in a focused ion beam system.

### DETAILED DESCRIPTION

The present invention and the various features and advantageous details thereof are explained more fully with reference to the nonlimiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the present invention. The examples used herein are intended merely to facilitate an understanding of ways in which the invention may be practiced and to further enable those of skill in the art to practice the invention. Accordingly, the examples should not be construed as limiting the scope of the invention.

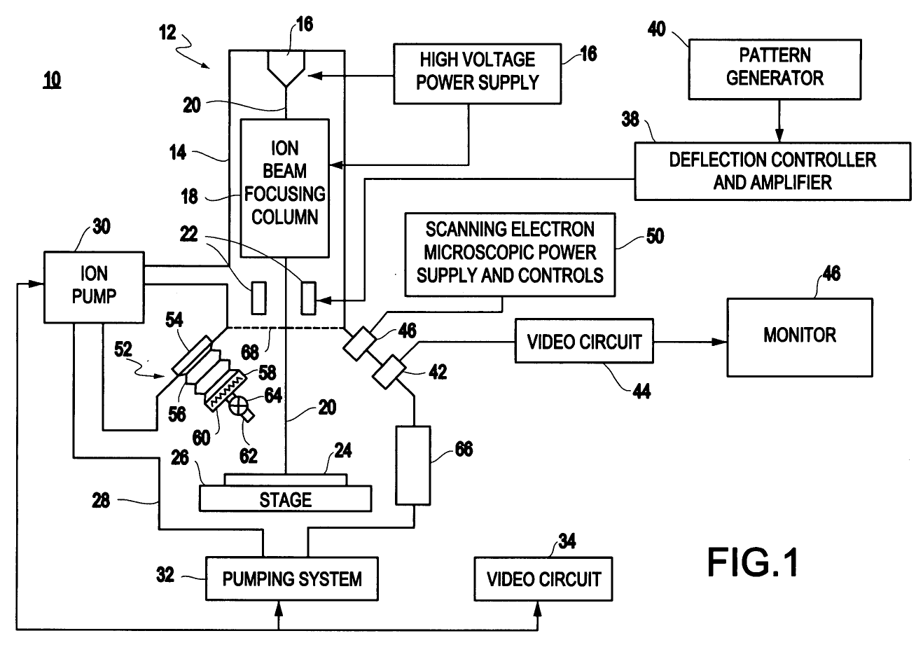

More specifically, as shown in co-pending patent application Ser. No. 10/604,110, filed Jun. 26, 2003, which is incorporated herein by reference. FIG. 1, depicts an exemplary focused ion beam system generally designated reference numeral 10. The disclosure is not intended to be limited to any particular focused ion beam system in this or in the following embodiments. Focused ion beam systems particularly suitable for use are systems having gas-assisted capabilities and imaging capabilities, e.g., a scanning electron microscope.

The system 10 includes an evacuated envelope 12 having an upper portion 14 within which are located a liquid metal ion source 16 and a focusing column 18 which includes extractor electrode means and an electrostatic optical system. Ion beam 20 passes from the liquid metal source 16 through focusing column 18 and between electrostatic deflection means (i.e., deflection plates), schematically indicated at 22, toward a substrate 24, which suitably comprises a semiconductor device positioned on a stage 26 within chamber 28. An ion pump 30 is employed for evacuating the upper portion 14. The chamber 28 is evacuated, preferably with a turbomolecular and mechanical pumping system 32 under the control of vacuum controller 34. High voltage power supply 36 is connected to the liquid metal ion source 16 as well as to appropriate electrodes in the ion beam focusing column 18 for forming an ion beam 20 and directing the same downwardly. Deflection controller and amplifier 38, operated in accordance with a prescribed pattern, such as a raster pattern, provided by pattern generator 40, is coupled to deflection plates 22, whereby ion beam 20 may be controlled to trace out a corresponding pattern on the upper surface of substrate 24.

The metal source 16 typically provides a metal ion beam of gallium (although other metallic ions can be used, for example indium or aluminum). The source is capable of being focused into a sub-0.1 micron width beam at substrate 24. An electron multiplier 42 used for detecting secondary emission for imaging is connected to a video circuit and amplifier 44, the latter supplying the drive for video monitor 46 also receiving deflection signals from deflection controller and amplifier 38. The evacuated envelope 12 preferably includes a scanning electron microscope (SEM) 46 that can be used to view the results of operations performed by the focused ion beam, or more preferably, that can perform electron beam processing. SEM 46 includes an electron beam generator and an associated power supply and controls 50.

A gas source 52 is located inwardly of the side of chamber 28 by a translation device 54 adapted for positioning the source 52 via support means within bellows 56. Bellows 56 accommodates movement of the nozzle assembly and reservoir relative to the substrate 24 without affecting the vacuum within chamber 28. Gas source 52 includes a reservoir 58 and a heater 60, which may comprise a membrane type heater and which may be used for raising the temperature of a compound within reservoir 58 to a temperature for providing a suitable vapor pressure in accordance with art recognized practices. A transfer tube or nozzle 62 comprising a capillary tube such as a hypodermic needle extends from reservoir 58 and is connected thereto via control valve 64 adapted for releasing gaseous vapor. The nozzle is extended and translated in orthogonal directions substantially perpendicular to its axis employing translation apparatus 54, so that gaseous vapor can be aimed directly toward a region on the top surface of substrate 24.

A door 66 is opened for inserting the substrate 24 onto stage 26 which may be heated, and also for servicing the reservoir 58. The door is preferably interlocked so that it cannot be opened if the temperature in reservoir 58 is substantially above room temperature. A gate valve, schematically illustrated at 68, is closed before door 66 can be opened to seal off the ion source and focusing column apparatus. Bellows 56 accommodates movement of the nozzle assembly 52 and reservoir relative to the substrate without affecting the vacuum within chamber 28.

The vacuum control system along with the heater of gaseous vapor source 52 are operated to provide an appropriate vapor pressure condition for establishing a gaseous vapor flux in chamber that is directed toward substrate 24 for selective etching. To establish a given gaseous flux, the reservoir 58 is heated to a predetermined temperature as is known by those skilled in the art.

The high voltage power supply 36 provides an appropriate acceleration voltage to electrodes in ion beam focusing column 18 for energizing and focusing ion beam 20.

When the ion beam 20 strikes the substrate 24 having condensed gaseous vapor adhered thereupon, the ion beam 20 provides energy for initiating a reaction between the etch-enhancing gaseous compound and the substrate as well as for sputter etching selected areas of the substrate. Deflection controller and amplifier 38 cause the ion beam 20 to be deflected in a desired pattern wherein deflection of the ion beam 20 is at a rate slow enough for etching substrate 24. Considerations regarding deflection speed, loop time, etc. are well within the skill of those in the art.

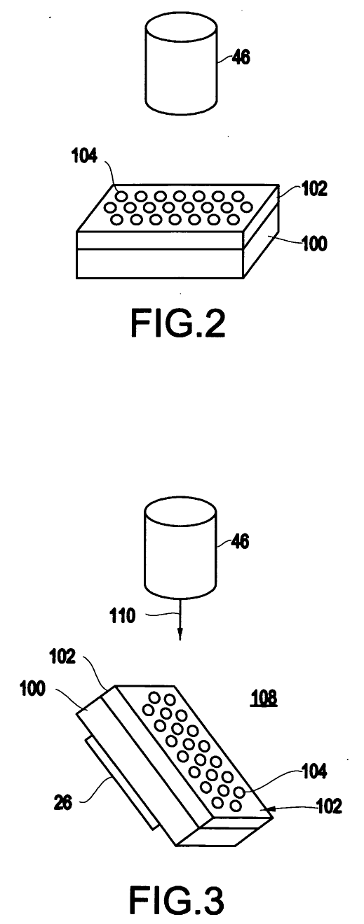

As shown in FIG. 2, the invention provides a method of inspecting topographical features, such as vias 104, of the top layer 102 of a partially completed structure 100 (e.g., integrated circuit). FIGS. 2-5 are simplified schematic drawings of the same (or similar) focused ion beam system shown in FIG. 1; however, many components have been omitted from FIGS. 2-5 to focus the reader's attention on the salient aspects of the invention.

More specifically, the invention surrounds the partially completed integrated circuit structure 100 with a precursor organic metal gas 108 and then directs an angled electron beam 110, from an ion beam generator 46, to the partially completed integrated circuit structure 100 to create secondary electron beams 604 (shown in FIG. 6) as the angled electron beam 110 strikes the sidewalls of the vias 104. The process of directing the angled electron beam can be performed for example, by tilting the stage 26 that supports the partially completed integrated circuit structure 100.

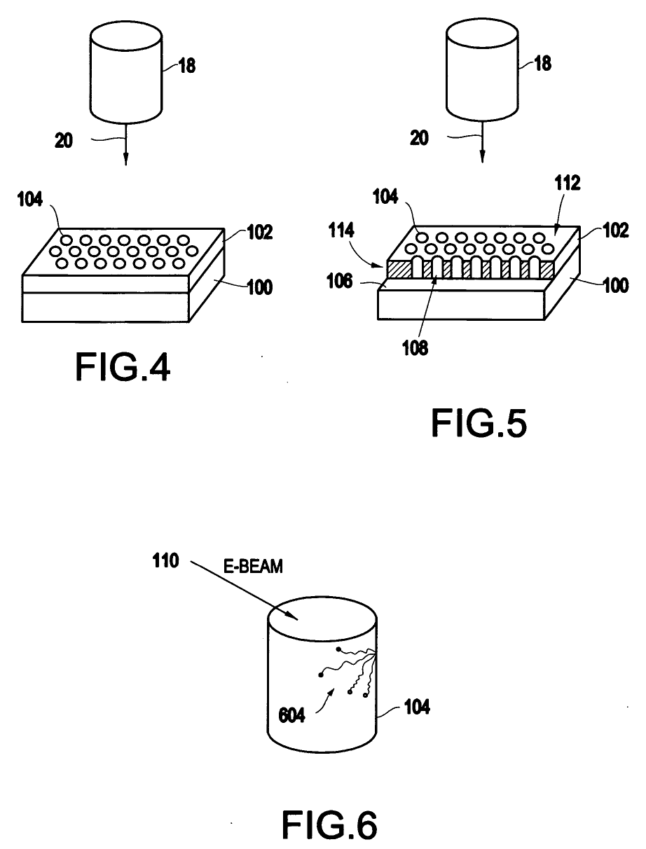

The secondary electron beams 604 break down the precursor metal gas to form a metal coating 112, without damaging the top layer 102 (or underlying layers 100). This process directs the electron beam 110 at an angle sufficient to cause the electron beam 110 to strike only the sidewalls of the vias 104 and prevent the electron beam 110 from reaching the bottom of the vias 104, so as to not damage the vias 104 during the metal formation process. The primary electron beam 110 does not substantially affect the sidewalls of features and can readily be directed at such sidewalls. Instead, the primary beam should be kept away from the bottom and lower level features, such as the ARC, to prevent damaging such lower level substances. After the protective metal layer 112 is formed (as shown in FIGS. 4 and 5) the invention directs an ion beam 20 from an ion beam generator 18 at the partially completed integrated circuit structure 100 to form a groove 114 within the top layer 102. This allows inspection of cross sections of the vias 104 exposed by the groove 114, as shown in FIG. 5.

The secondary electron beams 604 have much less energy than the angled electron beam 110 and the angled electron beam 110 has an energy level of approximately between 100 and 10,000 electron volts. The process of directing the angled electron beam 110 comprises directing the electron beam 110 at an angle between approximately 20 and 70 degrees with respect to the surface of the top layer of the partially completed integrated circuit structure 100.

Therefore, the invention forms a thin metal coating 112 to protect the contact profile (e.g., via 104) during ion beam cross-section processing. In one example, platinum-containing gas is used as the precursor 108 for metal de-position. The secondary electron beams 604 are used to break down the precursor gas to form the metal coating 112.

For example, the precursor could comprise Methylcyclopentadienyl platinum (with a trade name of Epigrade PT10, available from NovaMOS Division, Advanced Technology Materials, Inc. located in 7 Commerce Drive, Danbury, Conn. 06810, USA). Other precursors can also be used for this step. In one example, the primary electron beam has a power of 3 keV electron beam. However, the power level of the primary electron beam can range from 100 eV to 10 keV.

In one example, if a contact hole in a resist layer is to be imaged, the wafer can be tilted (e.g., 52 degrees) to minimize the direct contact of incoming electron beam with resist inside the surface of the contact hole. As would be understood by those ordinarily skilled in the art, the angle of the wafer with respect to primary electron beam will depend upon the shape of the features to be observed. The angle is preferably selected so that the shadowed area is the most sensitive area, which should not be directly reached by the incoming direct electron beam.

Sometimes, it is hard to prevent a certain amount of direct beam scanning on the surface. For example, when the surface is flat, if the beam is perpendicular to the surface (e.g., 90 degrees) the penetration depth is the deepest and the damage is also maximized. As the beam is scanned at increased angles, the damage will be reduced, but cannot be completely eliminated, even if the angle is zero degrees (i.e. parallel to the surface). As long as the portion of the direct electron beam is minimized on the interested feature surface, the feature profile will be better preserved during the deposition process.

Having the direct electron beam reach the bottom of the contact hole should be avoided. There are two reasons for this. First, the ARC layer, which underlies the resist and is exposed at the bottom of the contact hole, can be easily damaged by the direct beam during deposition process because of the existence of the precursor gas. Secondly, the damaged ARC material can be sputtered away from the bottom and redeposited on the sidewall of the contact hole, to blur or distort the profile of the contact hole sidewall in the final SEM image.

The optimal angle of the incoming direct beam will be dependent on the aspect ratio of height to diameter of the contact. The beam should be angled so that the direct beam does not hit the bottom of the contact hole. If the angle of the beam is 90 degrees (perpendicular to the surface) the metal deposition rate is the highest, but the damage to the resist profile is also the highest. If the beam is zero degrees (parallel to horizontal surface of the contact), there will be no metal deposition inside the contact hole, with zero damage to the profile. The best angle will have a reasonably rapid and uniform metal deposition with minimized damage to contact profile. For example, the angle could be around 45 degrees (in the range of 70 degrees to 20 degrees).

In one example, the coating process has the following parameters: Electron beam scanning conditions: energy=3 kev, dwell time=0.2 μs, overlap=−50%, scan size=5 μm×3 μm, scan time=4 minutes, precursor gas=open. Overlap definition is defined as the percentage of beam overlap between adjacent pixels in a digital scan of the beam across the area with the assumption that the beam is round with a fixed diameter. Also, for example, the ion beam milling could use an ion beam of 10 PA (picoamps). A lower beam current has a smaller spot size and produces less damage on the interested feature. Usually, less than 100 PA offers reasonable result. In one example, the milling parameters could be as follows: dwell time=0.2 μs; overlap of spot size=−50%, milling size=5 μm×3 μm×0.1 μm=Height×Width×Depth; box size and depth can change according to need, feature size and feature depth. The milling box is preferably small to barely larger than interested feature size. A small milling box produces less damage, because a larger box requires a larger total dose (which will cause more re-deposition of milled material).

In one example, the delineation process (i.e., used to clean the cross-section surface of re-deposited material prior to e-beam scanning for the SEM image) opens a XeF₂ gas nozzle positioned close to the milling crater for up to 5 seconds without electron beam pre-scanning; or the process can open the XeF₂ gas nozzle simultaneously with the electron beam scanning for up to 60 seconds, which offers the observer an opportunity to monitor the cleaning process with on-site image.

Using an electron beam to initiate metal deposition is usually slower than by Ion beam. The advantage is that electron beam does dramatically less damage on the specimen compared with regular ion beam. However, with perpendicular (90 degree) electron beam deposition, the specimen damage cannot be totally eliminated. Therefore, the invention utilizes an angled electron beam to reduce or eliminate the amount of damage. The amount of damage produced by the electron beam depends on the electron beam energy, target material Z value, material softness, topography, incoming beam direction, etc.

The electron beam can also be used for feature imaging, alignment, and as the energy source for initiating metal deposition. For regular electron imaging, the electron beam has an energy level around 1 kev. However, this energy level can damage a delicate resist (even with the existence of a metal deposition precursor). Since resist materials are relatively soft compared to other materials, such as dielectrics, the invention uses secondary (e.g., reflected, refracted, backscattered, etc.) electron beams to reduce the electron beam energy. If the primary electron beam energy was simply lowered to less than 1 keV, the beam spot size (focused electron beam diameter) would become too large and, therefore, resolution would quickly deteriorate. Such a large, low resolution beam cannot be easily controlled for real imaging usage.

When the primary electron beam hits a surface, the emitted electrons that have an energy level less than 50 eV are called secondary electrons, and those with an energy level of 50 eV or higher are called backscattered electrons. The lower power secondary electrons are usually much more abundant relative to backscattered electrons. The same electron beam can be shared for both imaging and deposition, where the direct beam is used for imaging, and the indirect beam is used for metal deposition to form a true protection layer without deforming or damaging the underlying resist feature because of the nature of the low energy of the indirect beam. The indirect electrons initiate the metal deposition (using the precursor gas). Thus, the present invention provides the indirect electron beam as an energy source to initiate metal coating with the existence of precursor gas, and also offers a coating technique to cover a wide range applications on the variety of materials, topography, shapes, etc.

The invention offers a novel technique to examine a contact profile in high resolution without damaging the original profile, which is very critical for new process development and optimization, defect analysis, production process monitoring, and especially when the feature size is less than 100 nm, and the material comprises a soft polymer like photo resist.

While the invention has been described in terms of preferred embodiments, those skilled in the art will recognize that the invention can be practiced with modification within the spirit and scope of the appended claims.

1. A method of inspecting topographical features of the top layer of a structure, said method comprising:
surrounding said structure with a precursor metal gas;
directing an angled electron beam at said structure to cause said precursor metal gas to form a metal coating on said structure;
directing an ion beam at said structure to form a groove within said top layer of said structure; and
inspecting said topographical features exposed by said groove in said top layer of said structure.

2. The method in claim 1, wherein said process of directing said angled electron beam directs said electron beam at an angle sufficient to cause said electron beam to strike the sidewalls of said topographical features.

3. The method in claim 1, wherein said process of directing said angled electron beam comprises tilting a stage that supports said structure.

4. The method in claim 1, wherein said process of directing said angled electron beam creates secondary electron beams as said angled electron beam strikes the sidewalls of said topographical features, wherein said secondary electron beams break down said precursor metal gas to form said metal coating.

5. The method in claim 4, wherein said secondary beams have less energy than said angled electron beam.

6. The method in claim 1, wherein said process of directing said angled electron beam comprises using an electron beam having an energy level of approximately between 100 and 10,000 electron volts.

7. The method in claim 1, wherein said process of directing said angled electron beam comprises directing said electron beam at an angle between approximately 20 and 70 degrees with respect to the surface of the top layer of said structure.

8. A method of inspecting topographical features of the top layer of a partially completed integrated circuit structure, said method comprising:
surrounding said partially completed integrated circuit structure with a precursor organic metal gas;
directing an angled electron beam at said partially completed integrated circuit structure to cause said precursor metal gas to form a metal coating on said partially completed integrated circuit structure;
directing an ion beam at said partially completed integrated circuit structure to form a groove within said top layer of said partially completed integrated circuit structure; and
inspecting cross sections of said topographical features exposed by said groove in said top layer of said partially completed integrated circuit structure.

9. The method in claim 8, wherein said process of directing said angled electron beam directs said electron beam at an angle sufficient to cause said electron beam to strike the sidewalls of said topographical features and prevent said electron beam from reaching the bottom of said topographical features.

10. The method in claim 8, wherein said process of directing said angled electron beam comprises tilting a stage that supports said partially completed integrated circuit structure.

11. The method in claim 8, wherein said process of directing said angled electron beam creates secondary electron beams as said angled electron beam strikes the side walls of said topographical features, wherein said secondary electron beams break down said precursor metal gas to form said metal coating.

12. The method in claim 11, wherein said secondary beams have less energy than said angled electron beam.

13. The method in claim 8, wherein said process of directing said angled electron beam comprises using an electron beam having an energy level of approximately between 100 and 10,000 electron volts.

14. The method in claim 8, wherein said process of directing said angled electron beam comprises directing said electron beam at an angle between approximately 20 and 70 degrees with respect to the surface of the top layer of said partially completed integrated circuit structure.

15. A method of inspecting vias of the top layer of a partially completed integrated circuit structure, said method comprising:
surrounding said partially completed integrated circuit structure with a precursor organic metal gas;
directing an angled electron beam at said partially completed integrated circuit structure to create secondary electron beams as said angled electron beam strikes the sidewalls of said vias, wherein said secondary electron beams break down said precursor metal gas to form a metal coating on said partially completed integrated circuit structure;
directing an ion beam at said partially completed integrated circuit structure to form a groove within said top layer of said partially completed integrated circuit structure; and
inspecting cross sections of said vias exposed by said groove in said top layer of said partially completed integrated circuit structure.

16. The method in claim 15, wherein said process of directing said angled electron beam directs said electron beam at an angle sufficient to cause said electron beam to strike the sidewalls of said vias and prevent said electron beam from reaching the bottom of said vias.

17. The method in claim 15, wherein said process of directing said angled electron beam comprises tilting a stage that supports said partially integrated circuit structure.

18. The method in claim 17, wherein said secondary beams have less energy than said angled electron beam.

19. The method in claim 15, wherein said process of directing said angled electron beam comprises using an electron beam having an energy level of approximately between 100 and 10,000 electron volts.

20. The method in claim 15, wherein said process of directing said angled electron beam comprises directing said electron beam at an angle between approximately 20 and 70 degrees with respect to the surface of the top layer of said partially completed integrated circuit structure.
